(19) United States
(12) Patent Application Publication
(10) Pub. No.: US 2026/0239698 A1
(43) Pub. Date: Aug. 13, 2026

(54) SEMICONDUCTOR STRUCTURE AND SEMICONDUCTOR DEVICE

(71) Applicant: Vanguard International Semiconductor Corporation, Hsinchu (TW)

(72) Inventors: Kuang-Hsuang LU, Hsinchu City (TW); Yu-Feng YAO, Taipei City (TW); Shyh-Chiang SHEN, Hsinchu City (TW)

(73) Assignee: Vanguard International Semiconductor Corporation, Hsinchu (TW)

(21) Appl. No.: 19/047,990

(22) Filed: Feb. 7, 2025

(51) Int. Cl. H10D 62/815; H10D 30/47; H10D 62/85

(52) U.S. Cl. CPC H10D 62/8164; H10D 30/475; H10D 62/8503

(57) ABSTRACT

A semiconductor structure is provided, including a substrate, a seed layer disposed on the substrate, and a buffer layer disposed on the seed layer. The buffer layer includes at least one superlattice part disposed on the seed layer and at least one block layer disposed on the superlattice part. The thickness of the block layer is 10 nanometers~600 nanometers. There is N1 superlattice part, and there is N2 block layer. Both N1 and N2 are positive integers and greater than or equal to 1.

### BACKGROUND OF THE INVENTION

### Field of the Invention

The present invention relates to a semiconductor structure, and in particular it relates to a semiconductor structure and a semiconductor device that reduce lattice dislocation.

### Description of the Related Art

In recent years, semiconductor structures have been used in various electronic products, such as high-power devices, computers, mobile phones, digital cameras and other electronic devices. Among these, high electron mobility transistor devices are widely used in light-emitting diodes (LED), components, and high-frequency components due to their gallium nitride-based semiconductor materials, which have many excellent material properties such as high thermal resistance, wide energy gap, high electron saturation rate, and the like.

Although the high electron mobility transistor devices produced in the prior art may generally meet their original intended uses, they still do not completely meet the requirements in all respects. For example, in current devices, lattice dislocations are likely to occur during epitaxial growth of semiconductor materials, resulting in reduced performance. Therefore, developing a semiconductor structure that can further improve the performance and reliability is still one of the current research topics in the industry.

### BRIEF SUMMARY OF THE INVENTION

Embodiments of the present invention provide a semiconductor structure, including a substrate, a seed layer located on the substrate, and a buffer layer located on the seed layer. The buffer layer includes at least one superlattice located on the seed layer and at least one block layer located on the at least one superlattice. The thickness of the block layer is 10 nanometers~600 nanometers. There is N1 superlattice part, and there is N2 block layer. Both N1 and N2 are positive integers and greater than or equal to 1.

In some embodiments, the thickness of the block layer is 30 nanometers~120 nanometers. In some embodiments, the block layer is AlN. In some embodiments, N1 is greater than N2 (N1>N2). In some embodiments, the difference between N1 and N2 is 1 (N1−N2=1).

In some embodiments, the block layer is sandwiched between any two of the at least one superlattice part. In some embodiments, the at least one block layer and the at least one superlattice part are stacked in a staggered manner.

In some embodiments, one of the at least one superlattice part comprises a plurality of repeating units that are stacked m1 times, wherein each of the repeating units comprises: a first sub-layer having a thickness of a1 nanometers; and a second sub-layer located on the first sub-layer and having a thickness of a2 nanometers, wherein m1 is a positive integer. In some embodiments, m1 is 20~120. In some embodiments, the first sub-layer is AlN, and the second sub-layer is AlGaN.

In some embodiments, when N1 is greater than or equal to 2 (N1≥2), the semiconductor has the following features.
(1) The total thickness of the superlattice part close to the substrate is less than the total thickness of the superlattice part far from the substrate.
(2) The thickness of the first sub-layer of each of the repeating units in the superlattice part close to the substrate is set as a11 nanometers, and the thickness of the first sub-layer of each of the repeating units in the superlattice part far from the substrate is set as a12 nanometers, where a11 is less than a12 (a11<a12).
(3) The thickness of the second sub-layer of each of the repeating units in the superlattice part close to the substrate is set as a21 nanometers, and the thickness of the second sub-layer of each of the repeating units in the superlattice part far from the substrate is set as a22 nanometers, where a21 is equal to a22 (a21=a22).
(4) The second sub-layer of each of the repeating units in the superlattice part close to the substrate is Alₓ₁Ga₁₋ₓ₁N, and the second sub-layer of each of the repeating units in the superlattice part far from the substrate is Alₓ₂Ga₁₋ₓ₂N, x1 is less than x2.
(5) The second sub-layer in each of the repeating units in the superlattice part close to the substrate has a first dopant with a first dopant concentration, and the second sub-layer of each of the repeating units in the superlattice part far from the substrate has a second dopant concentration with a second dopant concentration. The second dopant concentration is greater than, equal to, or less than the first dopant concentration. The first dopant and the second dopant are independently selected from carbon or iron. Alternatively, the first dopant and the second dopant may also be carbon and iron.

In some embodiments, the substrate comprises a base material and at least one insulating material. The at least one insulating material covers the base material.

In some embodiments, the semiconductor further includes a channel layer located on the buffer layer, a barrier layer located on the channel layer. In some embodiments, the semiconductor further includes a first compound semiconductor layer located between the buffer layer and the channel layer and a second compound semiconductor layer located on the barrier layer.

Embodiments of the present invention provide a semiconductor device, including the semiconductor structure mentioned above, a gate electrode located on the barrier layer, and a source electrode and a drain electrode located on opposite sides of the gate electrode. The semiconductor device is a high-electron mobility transistor (HEMT).

### BRIEF DESCRIPTION OF THE DRAWINGS

The present disclosure can be more fully understood by reading the subsequent detailed description and examples with references made to the accompanying drawings, wherein:

FIGS. 1-4 are schematic cross-sectional views illustrating a semiconductor structure according to some embodiments of the present invention.

FIG. 5 is schematic cross-sectional view illustrating a semiconductor device according to some embodiments of the present invention.

### DETAILED DESCRIPTION OF THE INVENTION

The following disclosure provides many embodiments or examples for implementing different elements of the provided semiconductor devices. Specific examples of each component and its configuration are described below to simplify the description of the embodiments of the present invention. Of course, these are only examples and are not intended to limit the embodiments of the present invention. For example, if a description mentions that a first component is formed on a second component, it may include an embodiment in which the first and second components are in direct contact, or may include an additional component formed between the first and second components, so that they are not in direct contact. In addition, embodiments of the present invention may repeat reference numbers and/or letters in different examples. This repetition is for the sake of brevity and clarity and is not intended to indicate the relationship between the various embodiments discussed.

Furthermore, spatially related terms may be used in the following descriptions, such as “under”, “below”, “underneath”, “above”, “over” and other similar terms are used to simplify the description of the relationship between one element or component and other elements or other components as shown in the figures. Such spatially relative terms include, in addition to the directions depicted in the figures, various orientations of the device during use or operation. The device may be otherwise oriented (rotated 90 degrees or at other orientations) and the spatially relative descriptors used herein interpreted accordingly.

Some variations of the embodiments are described below. Similar reference numbers are used to identify similar components in the various figures and illustrated embodiments. It will be appreciated that additional steps may be provided before, during, and after the method, and some of the recited steps may be replaced or deleted for other embodiments of the method.

Here, the terms “about” and “approximately” usually mean within 20% of a given value or range, preferably within 10%, and more preferably within 5%. The quantities given here are approximate quantities, which means that without specific explanation, the meaning of “approximately” or “approximately” may still be implied.

Embodiments of the present invention provide a semiconductor structure. The semiconductor structure includes a substrate, a seed layer located on the substrate, and a buffer layer located on the seed layer. The buffer layer includes at least one superlattice part located on the seed layer and at least one block layer located on the superlattice part. The thickness of the block layer is 10 nanometers~600 nanometers.

By arranging a block layer on the superlattice part, embodiments of the present invention may prevent the lattice dislocation from extending to the channel layer, the barrier layer and the like of subsequent epitaxial growth, thereby improving the performance of the semiconductor device. Moreover, by increasing the thickness of the block layer to a specific range, the occurrence of lattice dislocations in the film layer on the block layer may be further reduced, and the performance of the semiconductor device may be improved more effectively.

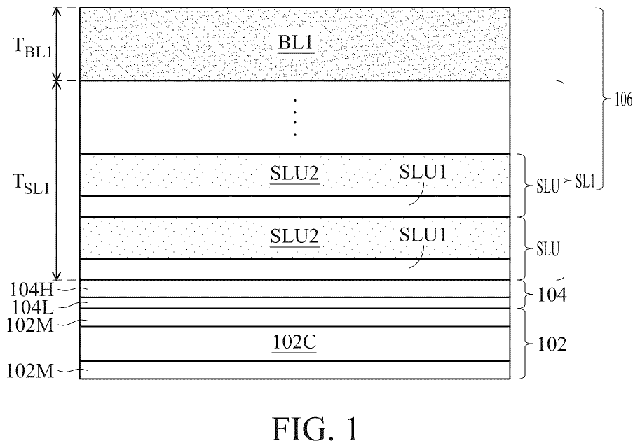

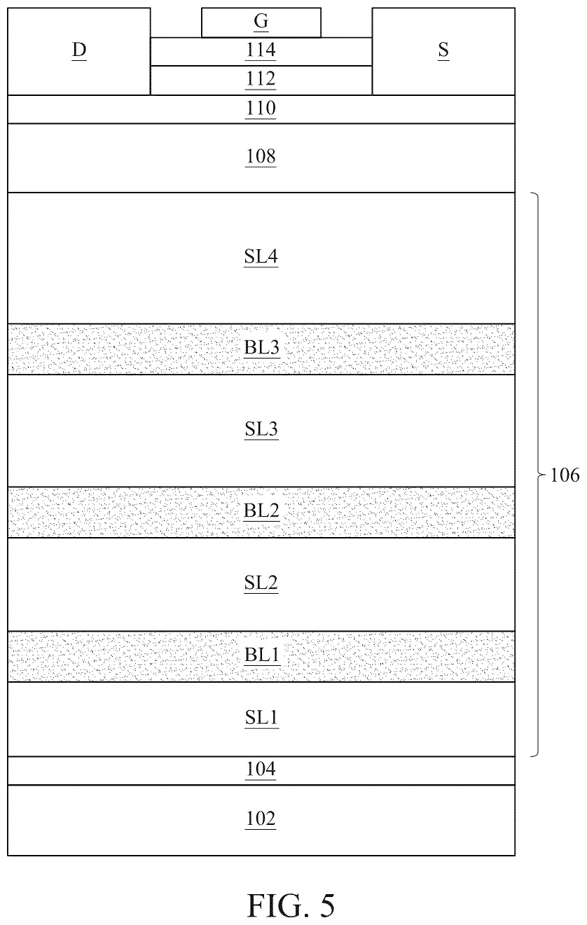

The present invention will be described in detail through specific embodiments below. FIGS. 1~4 illustrate exemplary cross-sectional views of the semiconductor structure in the embodiment of the present invention. FIG. 5 illustrates an exemplary cross-sectional view of a semiconductor device in the embodiment of the present invention.

As shown in FIG. 1, a substrate 102 is provided. In some embodiments, substrate 102 may be silicon on insulator (SOI).

In some embodiments, the substrate 102 includes a base material 102C and an insulating material 102M that encapsulates the base material 102C. The insulating material 102M may prevent the diffusion of the substrate 102C, and may also block the interaction of the substrate 102C with other film layers or process tools. In some embodiments, substrate 102C may include ceramic materials. Ceramic materials include metallic inorganic materials. In some embodiments, substrate 102C may include silicon carbide, aluminum nitride (AlN), sapphire, or other suitable materials. The above-mentioned sapphire is alumina. In some embodiments, the insulating material 102M may be a single or multiple layers of insulating materials covering all surfaces of the substrate 102C (including the upper and lower surfaces and all side surfaces). The insulating material layer is, for example, oxide, nitride, oxynitride, or other suitable insulating material. In some other embodiments, the insulating material 102M covering the surroundings of the substrate 102C may also include other suitable material layers, such as semiconductor layers, in addition to multiple layers of insulating material. In some embodiments, the semiconductor layer, such as a polycrystalline silicon layer, is disposed between the insulating material layers. In order to simplify the figures, only a single layer of insulating material layer 102M is shown in the figures to clearly illustrate the method of forming the semiconductor structure.

As shown in FIG. 1, a seed layer 104 is formed on the substrate 102. In some embodiments, the seed layer 104 may be formed of silicon (Si), aluminum nitride (AlN), or other suitable materials. In some embodiments, the seed layer 104 may include one or more layers of suitable materials. In some embodiments, the seed layer 104 may include a low temperature layer 104L grown at a low temperature and a high temperature layer 104H grown at a high temperature on the substrate 102. In some embodiments, both the low temperature layer 104L and the high temperature layer 104H are aluminum oxide (AlN). In some embodiments, the low temperature layer 104L has a thickness of approximately 0.5~2 nanometers (nm), and the high temperature layer 104H has a thickness of approximately 100~300 nanometers (nm). In some embodiments, after first forming island-shaped aluminum oxide (low temperature layer 104L) at a low temperature, aluminum oxide (high temperature layer 104H) with better quality is then formed at a high temperature to reduce subsequent lattice dislocation.

In some embodiments, the formation method of the seed layer 104 may include a selective epitaxial growth (SAG) process, a chemical vapor deposition (CVD) process, a molecular beam epitaxy process (MBE), a deposition of a doped amorphous semiconductor (such as Si) followed by a solid-phase epitaxial recrystallization (SPER) step, by direct transfer of seed crystals, or other appropriate manufacturing processes. Chemical vapor deposition processes include, for example, vapor-phase epitaxy (VPE) process, low pressure chemical vapor deposition (LPCVD) process, ultra-high vacuum chemical vapor deposition (UHV-CVD) process, or other suitable processes.

As shown in FIG. 1, a buffer layer 106 is formed on the seed layer 104. The buffer layer 106 may alleviate the stress-induced deformation (strain) of the channel layer subsequently formed above the buffer layer and prevent defects (such as the lattice dislocation) from being formed in the upper channel layer.

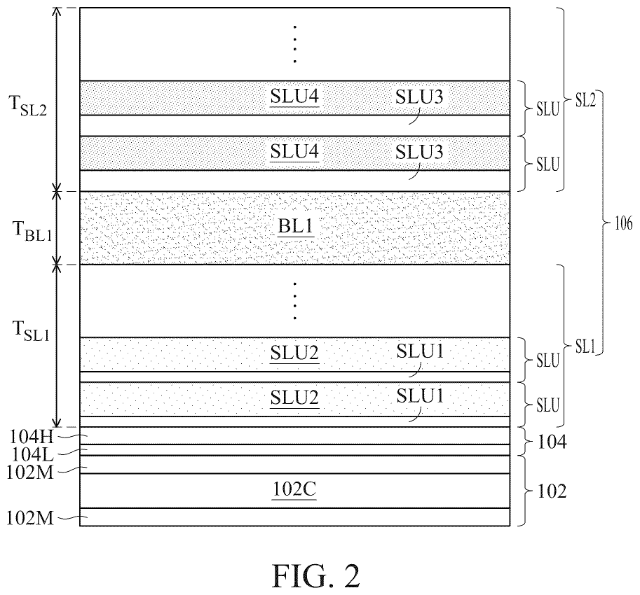

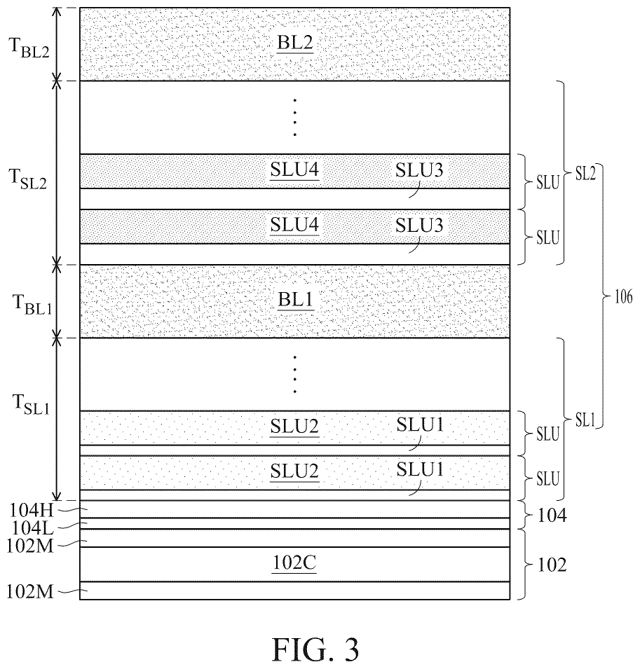

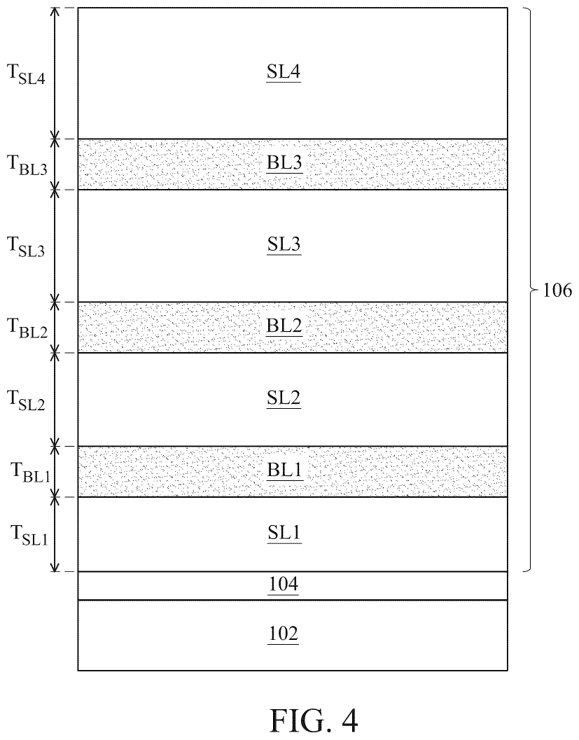

In some embodiments, the buffer layer 106 includes at least one superlattice part SL1 and at least one block layer BL1 located on the at least one superlattice part SL1. Specifically, there is N1 superlattice part SL1, and there is N2 block layer BL1, where both N1 and N2 are positive integers and greater than or equal to 1. The relationship between the quantity of superlattice parts and the quantity of block layers will be described in detail below through various embodiments. For example, the embodiment in FIG. 1 shows one superlattice part and one block layer (N1=1&N2=1); the embodiment in FIG. 2 shows two superlattice parts and one block layer (N1=2&N2=1); the embodiment in FIG. 3 shows two superlattice parts and two block layers (N1=2&N2=2); the embodiment in FIG. 4 shows four superlattice parts and three block layers (N1=4&N2=3). It should be noted that although the embodiments of this invention only disclose the quantity of the above-mentioned superlattice parts and block layers, as long as it does not exceed the scope of the claims of this invention, those with ordinary skill in the technical field to which the present invention belongs may apply the inventive concept of this case to arbitrarily increase and adjust the quantity of superlattice parts and block layers.

In the embodiment of FIG. 1, the buffer layer 106 includes a superlattice part SL1 and a block layer BL1. That is, N1 is 1 (N1=1) and N2 is 1 (N2=1). At this time, N1 is equal to N2 (N1=N2). Subsequently, to simplify the description, the superlattice part SL1 may also be called the first superlattice part SL1 and the block layer BL1 may also be called the first block layer BL1.

In some embodiments, the thickness T_{SL1} of the first superlattice part SL1 may be 800~6000 nanometers, or 1000~5000 nanometers, or 1500~4000 nanometers. In some embodiments, the first superlattice part SL1 may include a plurality of repeating units SLU stacked m1 times, where m1 is a positive integer. In some embodiments, m1 may be 20~120, or 30~100, or 40~80.

In some embodiments, each of the repeating units SLU in the first superlattice part SL1 includes a first sub-layer SLU1 and a second sub-layer SLU2 on the first sub-layer SLU1. The first sub-layer SLU1 has a thickness of a1 nanometers, and the second sub-layer SLU2 has a thickness of a2 nanometers.

In some embodiments, the first sub-layer SLU1 is thinner than the second sub-layer SLU2. That is, a1 is less than a2 (a1<a2). In some embodiments, a1 may be 1-14, and a2 may be 1-20.

In some embodiments, the first sub-layer SLU1 and the second sub-layer SLU2 may be III-V group semiconductor materials, such as aluminum nitride (AlN), aluminum gallium nitride (AlGaN), gallium arsenide (GaAs), gallium nitride (GaN), indium gallium nitride (InGaN), indium gallium phosphide (GaInP), aluminum gallium arsenide (AlGaAs), indium phosphide (InP), aluminum indium arsenide (InAlAs), indium gallium arsenide (InGaAs), other suitable III-V group materials, or a combination of the above. In the embodiment of the present invention, the first sub-layer SLU1 is aluminum nitride (AlN) and the second sub-layer SLU2 is aluminum gallium nitride (AlGaN).

In some embodiments, the first sub-layer SLU1 and the second sub-layer SLU2 may be formed by hydride vapor phase epitaxy (HVPE), molecular beam epitaxy (MBE), or metal organic chemical vapor deposition (MOCVD), a combination of the above methods or similar methods.

In some embodiments, a first block layer BL1 is disposed on the first superlattice part SL1. In some embodiments, the thickness of the first block layer BL1 may be 10 nanometers to 600 nanometers, preferably 20 nanometers to 300 nanometers, and preferably 30 nanometers to 120 nanometers. Please refer to Table 1 below:

TABLE 1

| | | | | | |
|---|---|---|---|---|---|
| thickness of | none | 33 nm | 50 nm | 66 nm | 100 nm |
| the block | | | | | |
| layer | | | | | |
| improved | — | 13% | 20% | 26% | 36% |
| performance | | | | | |

As above, when no block layer is disposed, the thickness of the block layer is showed as “none”. Compared with disposing the block layer, the thickness of the block layer is provided as 33 nm, 50 nm, 66 nm, and 100 nm may increase the performance by 13%, 20%, 26%, and 36% respectively.

In some embodiments, the block layer BL1 may be a III-V group semiconductor material, such as aluminum nitride (AlN), aluminum gallium nitride (AlGaN), gallium arsenide (GaAs), gallium nitride (GaN), indium gallium nitride (InGaN), indium gallium phosphide (GaInP), aluminum gallium arsenide (AlGaAs), indium phosphide (InP), aluminum indium arsenide (InAlAs), gallium indium arsenide (InGaAs), other appropriate III-V group materials or a combination of the above. In the embodiment of the present invention, since AlN is a type of superlattice material, aluminum nitride (AlN) is used as the material of the block layer BL1. This may reduce surface defects and provide better connection.

In some embodiments, the block layer BL1 may be doped or undoped. In the case where it is doped, the dopant may be carbon or iron to further reduce lattice dislocation in the upper channel layer. In some embodiments, the dopant concentration may be 1E15-1E20.

In some embodiments, the block layer BL1 may be formed by hydride vapor phase epitaxy (HVPE), molecular beam epitaxy (MBE), organic metal chemical vapor deposition (MOCVD), the combination of aforementioned methods or similar methods.

As above, by disposing the block layer BL1 on the superlattice part SL1, defects may be prevented from extending into the upper channel layer. Moreover, by increasing the thickness of the block layer BL1 to a specific range, defects in the upper channel layer may be reduced, thereby improving performance by 10%~50%.

Next, referring to FIG. 2, FIG. 2 is similar to FIG. 1. The difference between them is that the buffer layer 106 includes two superlattice parts SL1 and SL2. Specifically, in the embodiment of FIG. 2, the buffer layer 106 includes two superlattice parts SL1 and SL2 and a block layer BL1. That is, N1 is 2 (N1=2) and N2 is 1 (N2=1). At this time, N1 is greater than N2 (N1>N2) and the difference between N1 and N2 is 1 (N1−N2=1). Here, the superlattice part SL2 disposed on the block layer BL1 may also be called the second superlattice part SL2. In the embodiment of FIG. 2, the first block layer BL1 is sandwiched between the first superlattice part SL1 and the second superlattice part SL2.

In some embodiments, the thickness T_{SL2} of the second superlattice part SL2 is greater than or equal to the thickness T_{SL1} of the first superlattice part SL1 (T_{SL2}≥T_{SL1}). In other words, the thickness T_{SL1} of the first superlattice part SL1 close to the substrate 100 is less than or equal to the thickness T_{SL2} of the second superlattice part SL2 far from the substrate 100 (T_{SL1}≤T_{SL2}). In some embodiments, the thickness T_{SL2} of the second superlattice part SL2 may be 1000~7000 nanometers, or 1500~6000 nanometers, or 2000~5000 nanometers. In some embodiments, the second superlattice part SL2 may include a plurality of repeating units SLU stacked m2 times, where m2 is a positive integer. In some embodiments, m2 may be the same as m1 (m2=m1). For example, m2 may be 20~120, or 30~100, or 40~80. Alternatively, m2 may be greater than m1 (m2>m1). For example, m2 may be 30~150, or 40~120, or 50~100.

In some embodiments, each of the repeating units SLU in the second superlattice part SL2 is similar to each of the repeating unit SLU in the first superlattice part SL1. In detail, a third sub-layer SLU3 and a fourth sub-layer SLU4 included in each of the repeating units SLU in the second superlattice part SL2 are similar to the first sub-layer SLU1 and the second sub-layer SLU2. The third sub-layer SLU3 has a thickness of a3 nanometers, and the second sub-layer SLU4 has a thickness of a4 nanometers.

In some embodiments, the third sub-layer SLU3 is thinner than the fourth sub-layer SLU4. That is, a3 is less than a4 (a3<a4). In some embodiments, a3 may be 1-20, and a4 may be 1-20.

In some embodiments, the thickness of the first sub-layer SLU1 is less than the thickness of the third sub-layer SLU3. That is, a1 is less than a3 (a1<a3). In other words, the thickness of the first sub-layer SLU1 in the first superlattice part SL1 close to the substrate 100 is less than the thickness of the third sub-layer SLU3 in the second superlattice part SL2 far from the substrate 100.

In some embodiments, the thickness of the second sub-layer SLU2 is equal to the thickness of the fourth sub-layer SLU4. That is, a2 is equal to a4 (a2=a4). In other words, the thickness of the second sub-layer SLU2 in the first superlattice part SL1 close to the substrate 100 is approximately equal to the thickness of the fourth sub-layer SLU4 in the second superlattice part SL2 far from the substrate 100.

In some embodiments, the materials of the third sub-layer SLU3 and the fourth sub-layer SLU4 may be similar to or the same as those of the first sub-layer SLU1 and the second sub-layer SLU2. For example, the third sub-layer SLU3 is aluminum nitride (AlN) and the fourth sub-layer SLU4 is aluminum gallium nitride (AlGaN). In other embodiments, the second sub-layer SLU2 and the fourth sub-layer SLU4 may have different composition ratios of aluminum gallium nitride (AlGaN). For example, the second sub-layer SLU2 may be Alₓ₁Ga₁₋ₓ₁N, and the fourth sub-layer SLU4 may be Alₓ₂Ga₁₋ₓ₂N, where x1 is less than x2 (x1<x2). In other words, the second sub-layer SLU2 of the first superlattice part SL1 close to the substrate 100 has a lower molar fraction of aluminum (Al), and the fourth sub-layer SLU4 of the second superlattice part SL2 far from the substrate 100 has a higher molar fraction of aluminum (Al).

In some embodiments, the first sub-layer SLU1 and the second sub-layer SLU2 of the first superlattice part SL1 and the third sub-layer SLU3 and the fourth sub-layer SLU4 of the second superlattice part SL2 may be respectively be doped or undoped. In the case where it is doped, the dopant may independently be carbon or iron to further reduce lattice dislocation in the upper channel layer.

In other embodiments, the dopant concentration of the second sub-layer SLU2 of the first superlattice part SL1 close to the substrate 100 may be less than the dopant concentration of the fourth sub-layer SLU4 of the second superlattice part SL2 far from the substrate 100. Thereby, the lattice dislocation in the upper channel layer is further reduced.

In some embodiments, the formation of the second superlattice part SL2 is similar to the formation of the first superlattice part SL1, which will not be described again.

In other embodiments, when the first block layer BL1 is disposed between the first superlattice part SL1 and the second superlattice part SL2, a third superlattice part (not shown), a fourth superlattice part (not shown) or the like may also be directly disposed on the second superlattice part SL2 to facilitate stress buffering.

As above, by including two (or more) superlattice parts in the buffer layer, it is more conducive to stress buffering while preventing defects from being formed in the upper channel layer.

Next, referring to FIG. 3. FIG. 3 is similar to FIG. 2. The difference between them is that the buffer layer 106 includes two block layers BL1 and BL2. Specifically, in the embodiment of FIG. 3, the buffer layer 106 includes two superlattice parts SL1 and SL2 and two block layers BL1 and BL2. That is, N1 is 2 (N1=2) and N2 is 2 (N2=2). At this time, N1 is equal to N2 (N1=N2) and the difference between N1 and N2 is 0 (N1−N2=0). Here, the block layer BL2 disposed on the second superlattice part SL2 may also be referred to as the second block layer BL2. In the embodiment of FIG. 3, from bottom to top, there are the first superlattice part SL1, the first block layer BL1, the second superlattice part SL2 and the second block layer BL2. That is, the block layers BL1 and BL2 and the superlattice parts SL1 and SL2 are alternately stacked. Thereby, the lattice dislocation in the superlattice part may be further reduced from extending into the upper channel layer.

In some embodiments, the thickness T_{BL2} of the second block layer BL2 may be greater than, equal to, or less than the thickness T_{BL1} of the first block layer BL1. In some embodiments, the thickness T_{BL2} of the second block layer BL2 is approximately equal to the thickness T_{BL1} of the first block layer BL1 (T_{BL2}=T_{BL1}), thereby reducing costs while reducing defects formed in the upper channel layer. In some embodiments, the second block layer BL2 may be made of materials similar to the first block layer BL1, such as aluminum nitride (AlN), which will not be described again here.

As above, by including two (or more) block layers in the buffer layer, it is more conducive to preventing defects from forming in the upper channel layer.

Next, referring to FIG. 4, FIG. 4 is similar to FIG. 3. The difference between them is that the buffer layer 106 includes four superlattice parts SL1, SL2, SL3, and SL4 and three block layers BL1, BL2, and BL3. That is, N1 is 4 (N1=4) and N2 is 3 (N2=3). At this time, N1 is greater than N2 (N1>N2) and the difference between N1 and N2 is 1 (N1−N2=1). Here, the superlattice part SL3, the block layer BL3, and the superlattice part SL4 disposed on the second block layer BL2 may also be referred to as the third superlattice part SL3, the third block layer BL3, and the fourth superlattice part SL4, respectively. In the embodiment of FIG. 4, the first block layer BL1, the second block layer BL2, and the third block layer BL3 are respectively sandwiched between the first superlattice part SL1 and the second superlattice part SL2, sandwiched between the second superlattice part SL2 and the third superlattice part SL3, and sandwiched between the third superlattice part SL3 and the fourth superlattice part SL4. It should be noted that, in order to highlight the features of the embodiment of FIG. 4, all repeating units in the superlattice part are omitted and the substrate 102 and the seed layer 104 are simplified to be a single layer.

The following table will discuss the semiconductor performance improved by different quantities of superlattice parts and block layers based on one superlattice part (N1) and one block layer (N2).

TABLE 2

| | | | | |
|---|---|---|---|---|
| The quantity of | 1 | 2 | 2 | 4 |
| the superlattice | | | | |
| part (N1) | | | | |
| The quantity of | 1 | 1 | 2 | 3 |
| the block | | | | |
| layer (N2) | | | | |
| Improved | — | 10% | 20% | 30% |
| performance | | | | |

As above, as the quantity of superlattice parts (N1) and the quantity of block layers (N2) increase, the semiconductor performance may be improved more effectively. The reason is that by multiple superlattice parts and multiple block layers stacked in a staggered manner, defects may be reduced from being formed in the channel layer more effectively and are more conducive to stress buffering.

Next, referring to FIG. 5, FIG. 5 shows an example of a semiconductor device. The semiconductor device may be, for example, a high-electron mobility transistor (HEMT). In some embodiments, the semiconductor device of FIG. 5 utilizes the semiconductor structure of FIG. 4. That is, the semiconductor device in FIG. 5 further includes a channel layer 110 and a barrier layer 112 formed on the buffer layer 106.

As shown in FIG. 5, the channel layer 110 is formed on the buffer layer 106. In some embodiments, the channel layer 110 includes undoped III-V group semiconductor material. For example, the channel layer 110 may be formed of undoped gallium nitride (GaN), but the invention is not limited thereto. In other embodiments, the channel layer 110 is formed of unintentionally doped (UID) gallium nitride (GaN) and therefore has free carriers therein. In some other embodiments, the channel layer 110 includes aluminum nitride (AlN), aluminum gallium nitride (AlGaN), gallium arsenide (GaAs), gallium nitride (GaN), indium gallium nitride (InGaN), gallium indium phosphide (GaInP), aluminum gallium arsenide (AlGaAs), indium phosphide (InP), indium aluminum arsenide (InAlAs), indium gallium arsenide (InGaAs), other appropriate III-V group materials or a combination of the above. In some embodiments, the channel layer 110 may be formed using molecular beam epitaxy (MBE), hydride vapor phase epitaxy (HVPE), metal-organic chemical vapor deposition (MOCVD), other appropriate methods, or a combination of the above methods.

As shown in FIG. 5, a barrier layer 112 is formed on the channel layer 110. In some embodiments, barrier layer 112 may include doped or undoped III-V group semiconductor materials. For example, the barrier layer 112 may be formed of undoped aluminum gallium nitride (AlₓGa₁₋ₓN, where 0<x<1), but the invention is not limited thereto. In some other embodiments, the barrier layer 112 may also include aluminum nitride (AlN), aluminum gallium nitride (AlGaN), gallium arsenide (GaAs), gallium nitride (GaN), indium gallium nitride (InGaN), gallium indium phosphide (GaInP), aluminum gallium arsenide (AlGaAs), indium phosphide (InP), indium aluminum arsenide (InAlAs), indium gallium arsenide (InGaAs), other appropriate III-V group materials or a combination of the above. For example, the barrier layer 112 may be formed on the channel layer 110 using molecular beam epitaxy, organic metal chemical vapor deposition, hydride vapor epitaxy, other appropriate methods or a combination of the above methods.

In some embodiments, the channel layer 110 and the barrier layer 112 may include different materials, such as gallium nitride (GaN) and aluminum gallium nitride (AlGaN), respectively. A heterogeneous interface is formed between layers 112. Through the band gap of the heterogeneous materials, a two-dimensional electron gas (2DEG) (not shown) may be formed on the heterogeneous interface. The semiconductor devices formed according to some embodiments, such as high electron mobility transistor (HEMT) devices, may utilize two-dimensional electron gas as conductive carriers.

In addition, in addition to the channel layer 110 and the barrier layer 112, the embodiment of FIG. 5 may further include a carbon-doped first compound semiconductor layer 108 to increase the breakdown voltage of the semiconductor device. As shown in FIG. 5, the first compound semiconductor layer 108 is formed on the buffer layer 106 to serve as an electrical buffer layer. In some embodiments, the first compound semiconductor layer 108 may be carbon-doped gallium nitride (C-GaN).

In addition, in addition to the channel layer 110 and the barrier layer 112, the embodiment of FIG. 5 may further include a second compound semiconductor layer 114 to serve as a switch of the semiconductor device. In the embodiment of FIG. 5, an enhanced mode (normally-off) high electron mobility transistor is produced as an example. In some embodiments, the second compound semiconductor layer 114 may be a III-V group semiconductor material doped with P-type dopants, such as aluminum gallium nitride (AlGaN) or gallium nitride (GaN), aluminum nitride (AlN), gallium arsenide (GaAs), indium gallium phosphide (GaInP), aluminum gallium arsenide (AlGaAs), indium phosphide (InP), indium aluminum arsenide (InAlAs), indium gallium arsenide (InGaAs), other suitable III-V materials, or a combination of the foregoing doped with P-type dopants. In some embodiments, the second compound semiconductor layer 114 may be formed of gallium nitride doped with P-type dopants (P-GaN). In some embodiments, the formation method of the second compound semiconductor layer 114 may include atomic layer deposition, chemical vapor deposition, physical vapor deposition, epitaxial process, ion implantation or in-situ doping process.

In addition, the embodiment of FIG. 5 may further include a gate electrode G, and a source electrode S and a drain electrode D respectively formed on opposite sides of the gate electrode G.

In some embodiments, the gate electrode G is connected to the second compound semiconductor layer 114. A Schottky contact is formed between the gate electrode G and the second compound semiconductor layer 114. In some embodiments, the gate electrode G may include metal materials, metal silicides, polycrystalline silicon, other suitable conductive materials, or combinations thereof. In some embodiments, the gate electrode G may be formed by atomic layer deposition, chemical vapor deposition, physical vapor deposition (such as sputtering) or similar processes.

In some embodiments, the source electrode S and the drain electrode D are formed on opposite sides of the gate electrode G respectively. In some embodiments, as shown in FIG. 5, the source electrode S and the drain electrode D are located on the channel layer 110 and are in electrical contact with the channel layer 110. In some embodiments, the source electrode S and the drain electrode D include conductive materials, such as gold (Au), nickel (Ni), platinum (Pt), palladium (Pd), iridium (Ir), titanium (Ti), chromium (Cr), tungsten (W), aluminum (Al), copper (Cu), tantalum nitride (TaN), titanium nitride (TiN), tungsten silicide (WSi₂), combinations of the above or similar materials. In some embodiments, the source electrode S and the drain electrode D may be formed by atomic layer deposition, chemical vapor deposition, physical vapor deposition (such as sputtering), electron beam evaporation, or similar processes. In some embodiments, after depositing the material layer to form the source electrode S and the drain electrode D, a high-temperature thermal process such as a rapid thermal annealing process is further performed to form the source-drain ohmic contact.

In summary, embodiments of the present invention provide the buffer layer including the block layer, which may block the lattice dislocation from extending to the upper channel layer and the like, so as to improve the performance of the semiconductor device. Furthermore, by increasing the thickness of the block layer to a specific range, the occurrence of lattice dislocation in the film layer on the block layer may be further reduced. In addition, by the block layer sandwiched between the plurality of superlattice parts, the lattice dislocation in the upper film layer may be reduced more effectively. In addition, by multiple block layers and multiple superlattice parts stacked in a staggered manner, the occurrence of lattice dislocation in the upper film layer may be further reduced. Thereby, semiconductor performance is improved.

Although the embodiments and advantages of the present disclosure have been disclosed above, it should be understood that anyone with ordinary knowledge in the art may make changes, substitutions and modification without departing from the spirit and scope of the disclosure. In addition, the protection scope of the present disclosure is not limited to the processes, machines, manufacturing, material compositions, devices, methods and steps in the specific embodiments described in the specification. Anyone with ordinary knowledge in the relevant technical field may learn from some implementations of the present disclosure. It is understood that processes, machines, manufacturing, material compositions, devices, methods and steps currently or developed in the future may be based on the disclosure of the examples as long as they may perform substantially the same functions or obtain substantially the same results in the some embodiments of the present disclosure described herein. Therefore, the protection scope of the present disclosure includes the above-mentioned processes, machines, manufacturing, material compositions, devices, methods and steps. In addition, each claimed patent scope constitutes an individual embodiment, and the protection scope of the present disclosure also includes the combination of each claimed patent scope and embodiments.

What is claimed is:

1. A semiconductor structure, comprising:
a substrate;
a seed layer located on the substrate; and
a buffer layer located on the seed layer,
wherein the buffer layer comprises:
at least one superlattice part located on the seed layer, wherein there is N1 superlattice parts; and
at least one block layer located on the superlattice part, wherein there is N2 block layer,
wherein a thickness of the block layer is 10 nanometers~600 nanometers,
wherein both N1 and N2 are positive integers and greater than or equal to 1.

2. The semiconductor structure as claimed in claim 1, wherein the thickness of one of the at least one block layer is 30 nanometers~120 nanometers.

3. The semiconductor structure as claimed in claim 1, wherein the at least one block layer is AlN.

4. The semiconductor structure as claimed in claim 1, wherein N1 is greater than or equal to N2.

5. The semiconductor device as claimed in claim 1, wherein the difference between N1 and N2 is 1.

6. The semiconductor structure as claimed in claim 5, wherein the at least one block layer is sandwiched between any two of the at least one superlattice part.

7. The semiconductor structure as claimed in claim 5, wherein the at least one block layer and the at least one superlattice part are stacked in a staggered manner.

8. The semiconductor structure as claimed in claim 1, wherein a thickness of the superlattice part close to the substrate is less than a thickness of the superlattice part far from the substrate when N1 is greater than or equal to 2.

9. The semiconductor structure as claimed in claim 1, wherein one of the at least one superlattice part comprises a plurality of repeating units that are stacked m1 times, wherein each of the repeating units comprises:
a first sub-layer having a thickness of a1 nanometers; and
a second sub-layer located on the first sub-layer and having a thickness of a2 nanometers,
wherein m1 is a positive integer.

10. The semiconductor structure as claimed in claim 9, wherein the first sub-layer is AlN, and the second sub-layer is AlGaN.

11. The semiconductor structure as claimed in claim 9, wherein a1 is less than a2.

12. The semiconductor structure as claimed in claim 9, wherein m1 is 20~120.

13. The semiconductor structure as claimed in claim 9, wherein a thickness of the first sub-layer of each of the repeating units in the superlattice part close to the substrate is set as a11 nanometers, and a thickness of the first sub-layer of each of the repeating units in the superlattice part far from the substrate is set as a12 nanometers, wherein a11 is less than a12.

14. The semiconductor structure as claimed in claim 9, wherein a thickness of the second sub-layer of each of the repeating units in the superlattice part close to the substrate is set as a21 nanometers, and a thickness of the second sub-layer of each of the repeating units in the superlattice part far from the substrate is set as a22 nanometers, where a21 is equal to a22 when N1 is greater than or equal to 2.

15. The semiconductor structure as claimed in claim 9, wherein the second sub-layer of each of the repeating units in the superlattice part close to the substrate has a first dopant with a first dopant concentration, and the second sub-layer of each of the repeating units in the superlattice part far from the substrate has a second dopant with a second dopant concentration, where the second dopant concentration is greater than or equal to the first dopant concentration when N1 is greater than or equal to 2.

16. The semiconductor structure as claimed in claim 15, wherein the first dopant and the second dopant are independently carbon or iron or a combination of the foregoing.

17. The semiconductor structure as claimed in claim 1, wherein the substrate comprises a base material and at least one insulating material, wherein the at least one insulating material covers the base material.

18. The semiconductor structure as claimed in claim 1, further comprising:
a channel layer located on the buffer layer; and
a barrier layer located on the channel layer.

19. The semiconductor structure as claimed in claim 18, further comprising:
a first compound semiconductor layer located between the buffer layer and the channel layer; and
a second compound semiconductor layer located on the barrier layer.

20. A semiconductor device, comprising:
the semiconductor structure as claimed in claim 18;
a gate electrode located on the barrier layer;
a source electrode and a drain electrode located on opposite sides of the gate electrode.
